(19) United States
(12) Patent Application Publication
(10) Pub. No.: US 2026/0026084 A1
(43) Pub. Date: Jan. 22, 2026

(54) HIGH-ISOLATION P-SUBSTRATE IN RF PMOS TRANSISTOR

(71) Applicant: Taiwan Semiconductor Manufacturing Company, Ltd., Hsinchu (TW)

(72) Inventors: Hong-Shen Chen, Hsinchu (TW); Wu-Chen Lin, New Taipei City 242 (TW); Hsieh-Hung Hsieh, Taipei City (TW)

(73) Assignee: Taiwan Semiconductor Manufacturing Company, Ltd., Hsinchu (TW)

(21) Appl. No.: 18/930,744

(22) Filed: Oct. 29, 2024

Related U.S. Application Data
(60) Provisional application No. 63/672,920, filed on Jul. 18, 2024.

(51) Int. Cl. H01L 27/06; H03F 3/16

(52) U.S. Cl. CPC H10D 84/811; H03F 3/16; H03F 2200/294

(57) ABSTRACT

A semiconductor device includes a substrate having a first conductive type, a well region formed within the substrate and having a second conductive type opposite to the first conductive type, and a first transistor formed based on the well region. The first transistor includes a gate contact, a drain contact with the first conductive type, a source contact with the first conductive type, and a bulk contact with the second conductive type. The semiconductor device also includes an isolation circuit formed over the substrate and coupled between the substrate and a ground voltage through a substrate contact.

### CROSS-REFERENCE TO RELATED APPLICATION

This application claims priority to and the benefit of U.S. Provisional Application No. 63/672,920, filed Jul. 18, 2024, which is incorporated herein by reference in its entirety for all purposes.

### BACKGROUND

Millimeter-wave frequencies generally refer to signals in the frequency band between approximately 30 GHz to 300 GHz, which are frequently used in various applications such as wireless personal area networks (“WPANs”), automobile radar, and image sensing. Various low noise amplifiers (LNAs) for millimeter waves have been disclosed. However, LNAs implemented using compound III-V semiconductors or BJTs are not easily integrated with the other components of the receiver, especially for digital circuits, resulting in higher implementation costs. For example, recent advances in complementary metal oxide semiconductor (“CMOS”) technologies have enabled millimeter-wave integrated circuits to be implemented at lower costs as multi-stage LNAs. To obtain sufficient amplification, LNAs are typically implemented with at least two stages with input, output, and inter-stage matching networks.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram that illustrates an embodiment of a cascode amplifier in accordance with some embodiments.

FIG. 2 is a circuit diagram that illustrates another embodiment of a cascode amplifier including a source degeneration circuit in accordance with other embodiments.

FIGS. 3-5 are schematic views that illustrate various embodiments of isolation circuits in FIG. 2 in accordance with some embodiments.

FIG. 6 is a cross-sectional view that illustrates an example transistor of a cascode amplifier in FIG. 1 in accordance with some embodiments.

FIG. 7 is a plan view that illustrates an example transistor of a cascode amplifier in FIG. 6 in accordance with some embodiments

FIG. 8 is a cross-sectional view that illustrates two transistors of a cascode amplifier in FIG. 1 in accordance with some embodiments.

FIG. 9 is a plan view that illustrates two transistors of a cascode amplifier in FIG. 1 in accordance with some embodiments.

FIG. 10 is flow diagram that illustrates an example method of forming a cascode amplifier in accordance with some embodiments.

FIG. 11 is a graph that compares the gain performance of a cascode amplifier formed from a transistor having an isolation circuit that electrically couples a substrate thereof to the ground in accordance with the present disclosure to the gain performance of a cascode amplifier formed from transistors without such an isolation circuit.

FIG. 12 is a graph that compares the transconductance performance of a cascode amplifier formed from a transistor having an isolation circuit that electrically couples a substrate thereof to the ground in accordance with the present disclosure to the transconductance performance of a cascode amplifier formed from transistors without such an isolation circuit.

FIG. 13 is a graph that compares the gain vs frequency performance of a cascode amplifier formed from a transistor having an isolation circuit that electrically couples a substrate thereof to the ground in accordance with the present disclosure to the gain vs frequency performance of a cascode amplifier formed from transistors without such an isolation circuit.

FIG. 14 is a graph that compares the power-added-efficiency (PAE) vs input power (Pin) performance of a cascode amplifier formed from a transistor having an isolation circuit that electrically couples a substrate thereof to the ground in accordance with the present disclosure to the PAE vs Pin performance of a cascode amplifier formed from transistors without such an isolation circuit.

FIG. 15 is a schematic view that illustrates an embodiment of a cascode amplifier in which PMOS and NMOS substrates are used in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Low Noise Amplifiers (LNAs) and cascode amplifiers are both important components in RF and microwave circuits, particularly in communication systems. They are often used in different stages of a signal chain to amplify weak signals while minimizing noise and maintaining signal integrity. LNAs are amplifiers specifically designed to amplify weak signals without significantly degrading the signal-to-noise ratio (SNR). LNAs are often the first stage in a receiver chain, making their performance critical for the overall system noise figure. The main goal of an LNA is to have a low noise figure, meaning it introduces minimal additional noise to the signal, which is crucial for maintaining the quality of the received signal. LNAs provide significant amplification to boost weak signals to a level where further processing can occur without significant degradation. A cascode amplifier is a two-stage amplifier configuration that consists of a common-emitter (or common-source in FETs) stage followed by a common-base (or common-gate in FETs) stage, and thus provides high gain, improved bandwidth, and better isolation between the input and output. The cascode configuration enhances the overall gain of the amplifier by effectively stacking two transistors, which also helps in minimizing Miller capacitance (which would otherwise limit bandwidth). The cascode amplifier has a wide bandwidth because the Miller effect is reduced due to the configuration, making it suitable for high-frequency applications. The cascode arrangement offers better isolation between the input and output, which improves stability and reduces the risk of oscillations. The cascode configuration can help the LNA achieve higher gain and better isolation without compromising the noise figure significantly. LNAs and cascode amplifiers are often used together in RF design to leverage the strengths of each. For example, an LNA is primarily used to amplify weak signals with minimal noise, while the cascode amplifier configuration helps achieve this with improved gain and bandwidth characteristics.

The present disclosure provides various embodiments of a semiconductor device. In some embodiments, a semiconductor device includes a substrate having a first conductive type; a well region formed within the substrate and having a second conductive type opposite to the first conductive type; a first transistor formed based on the well region, in which the first transistor includes a gate contact, a drain contact with the first conductive type, a source contact with the first conductive type, and a bulk contact with the second conductive type; and an isolation circuit formed over the substrate and coupled between the substrate and a ground voltage through a first substrate contact adjacent to the first transistor. In some embodiments, the isolation circuit comprises a first resistor having a resistance greater than about 10 k ohm. In some embodiments, the semiconductor device includes the first transistor, and a second transistor coupled to the first transistor in series, in which the first transistor is configured to function as a common-gate (CG) stage of a cascode amplifier, and a second transistor is configured to function as a common-source (CS) stage of the cascode amplifier. In some embodiments, the second transistor includes a source contact and a bulk contact that are commonly coupled to a supply voltage (e.g., V_{DD}) via a source degeneration circuit, thus not directly coupled to the supply voltage V_{DD}, and another isolation circuit is formed over the substrate and configured to couple the substrate to the ground voltage (GND) through a second substrate contact that is adjacent to the second transistor.

For a cascode amplifier, including two stages, such as a common-source (CS) stage and a common-gate (CG) stage, coupled in series, an output of the CS stage is connected to an input of the CG stage. In one situation, in the CG stage, where the bulk and the source of the CG stage are not directly connected to a supply voltage (V_{DD})), there exists substrate-induced loss from the well region (e.g., N-well) or the substrate (e.g., p-doped substrate) of the CG stage, thereby resulting in gain degradation. In another situation, in the CS stage, in case that the bulk and the source of the CS stage are connected to a supply voltage (V_{DD}) through a source degeneration circuit (thus not directly connected to the supply voltage), there exists substrate-induced loss from the well region (e.g., N-well) or the substrate (e.g., p-doped substrate) of the CS stage, thereby resulting in gain degradation. In order to avoid such gain degradations, it is necessary to minimize the substrate-induced loss from the well region or the substrate. With at least an isolation circuit formed over the substrate and coupled between the substrate and a ground voltage (GND) through a substrate contact adjacent to the CG stage or the CS stage, the substrate-induced loss from well region or the substrate to the supply voltage can be reduced or even blocked, thereby advantageously reducing the gain degradation of the amplifier. The amplifier can be an low noise amplifier (LNA) or a power amplified (PA).

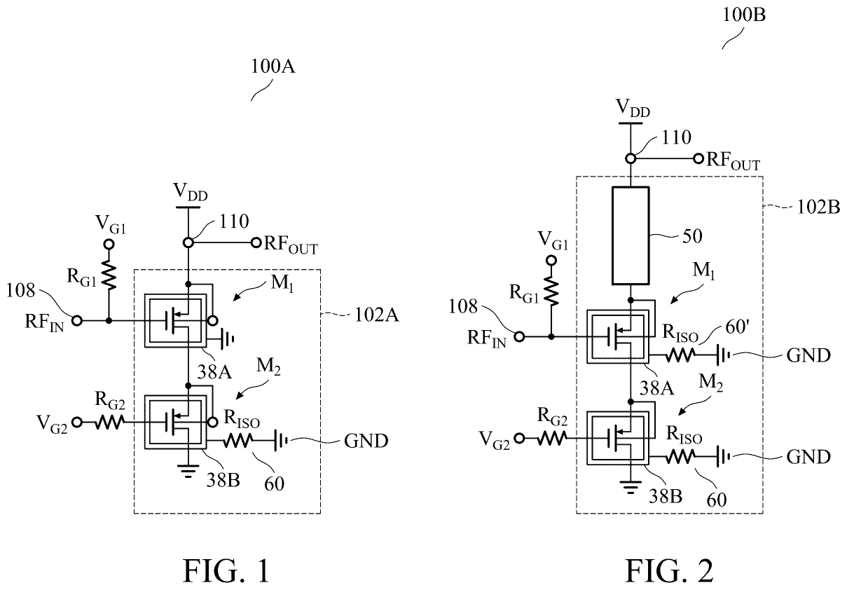

FIG. 1 is a circuit diagram that illustrates an embodiment of a cascode amplifier 100A in accordance with some embodiments. As shown in FIG. 1, the cascode amplifier 100A includes a cascode gain stage 102A including a common-source (CS) stage or transistor M₁ (104) coupled to a common-gate (CG) stage or transistor M₂. In some embodiments, the cascode amplifier 100A is formed over a substrate. Each of the circuit elements of the cascode amplifier 100A may be implemented using p-type metal-oxide-semiconductor (PMOS) technology, n-type metal-oxide-semiconductor (NMOS) technology, or complementary metal oxide semiconductor (“CMOS”) technology.

In some embodiments, as shown in FIG. 1, the CS transistor M₁ has its source directly coupled to node 110, which is coupled to a high voltage supply (V_{DD}), its bulk coupled to its source, its drain coupled a source of CG transistor M₂, and its gate coupled to an input node 108 to receive to an input signal RF_{IN} (such as an oscillating input signal). In some embodiments, the gate of the CS transistor M₁ is also coupled to a bias voltage source having a voltage V_{G1} via a resistor R_{G1}. In some embodiments, the node 110 also serves as an output node of the cascode amplifier 100A, and an output signal, RF_{OUT}, is output from the node 110. In some embodiments, a substrate guard ring 38A of the CS transistor M₁ serves as a substrate contact, and is coupled to the ground voltage (GND).

In some embodiments, as shown in FIG. 1, the CG transistor M₂ has its source coupled the drain of the CS transistor M₁, its bulk coupled to its source, its drain directly coupled the ground voltage (GND), and its gate coupled to another bias voltage source having a voltage V_{G2} via another resistor R_{G2}. In some embodiments, a substrate guard ring 38B of the CG transistor M₂ serves as a substrate contact, and is coupled to the ground voltage (GND) through an isolation circuit 60. In some embodiments, the isolation circuit 60 is formed over the substrate to couple the substrate guard ring 14 to the ground voltage (GND). In some embodiments, the isolation circuit 60 has a large resistance greater than 1 k ohm.

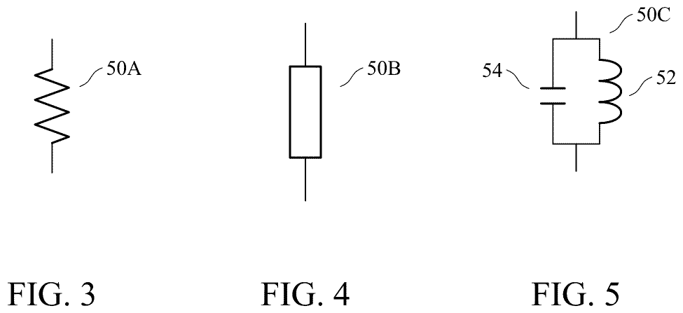

FIG. 2 is a circuit diagram that illustrates another embodiment of a cascode amplifier 100B in accordance with other embodiments. In some embodiments, as shown in FIG. 2, the cascode amplifier 100B is similar to the cascode amplifier 100A in FIG. 1, except that CS transistor M₁ of the cascode amplifier 100B includes a source degeneration circuit 50 that couples its source to the high supply voltage V_{DD}, such that the bulk and the source of the CS transistor M₁ are not directly connected to the high supply voltage V_{DD}, and thus a substrate guard ring 12 of the CS transistor M₁ of the cascode amplifier 100B is coupled to the ground voltage (GND) through an isolation circuit 60′. Details about various implementations of source degeneration circuits 50 will be described with respect to FIGS. 3, 4 and 5. In some embodiments, the isolation circuit 60′ is formed over the substrate of the cascode amplifier 100B configured to couple the substrate to the ground voltage (GND) through the substrate guard ring 38A as a substrate contact adjacent to the CS transistor M₁. In some embodiments, similar to the cascode amplifier 100A as shown in FIG. 1, an isolation circuit 60 is formed over the substrate of the cascode amplifier 100B as shown in FIG. 2 to couple the substrate to the ground voltage through the substrate guard ring 38B as another substrate contact adjacent to the CG transistor M₂. Each of the circuit elements of the cascode amplifier 100B may be implemented using p-type metal-oxide-semiconductor (PMOS) technology, n-type metal-oxide-semiconductor (NMOS) technology, or complementary metal oxide semiconductor (“CMOS”) technology.

FIGS. 3, 4 and 5 are schematic views that illustrate various embodiments of source degeneration circuits 50 in FIG. 2 in accordance with some embodiments. A source degeneration circuit 50 in FIG. 2 may be implemented in a variety of ways. Referring to FIG. 3, in some embodiments, the source degeneration circuit 50 in FIG. 2 is implemented as a resistor 50A that has a large resistance. In some embodiments, the resistance of the resistor 50A is equal to or greater than 3 k ohm. In other embodiments, the resistance of the resistor 50A is equal to or greater than 10 k ohm. Referring to FIG. 4, in other embodiments, source degeneration circuit 50 in FIG. 2 is implemented as a quarter wavelength transmission line 50B. A quarter-wavelength transmission line 50B is a section of transmission line that is exactly one-quarter of the wavelength (λ/4) of the signal frequency in length. A quarter-wavelength transmission line 50B is useful in RF and microwave engineering in various applications, such as impedance matching, filters, and antennas. The wavelength (λ) is determined by the signal frequency and the propagation speed of the wave in the medium, which is influenced by the dielectric material of the transmission line. Referring to FIG. 5, in still other embodiments, the source degeneration circuit 50 in FIG. 2 is implemented as an LC tank circuit 50C that includes an inductor 52 and a capacitor 54 that are disposed in parallel with each other and connected together in a loop. The LC tank circuit 50C exhibits a resonant behavior, and can store and exchange energy between the inductor 52 and capacitor 54, oscillating at a particular frequency known as the resonant frequency.

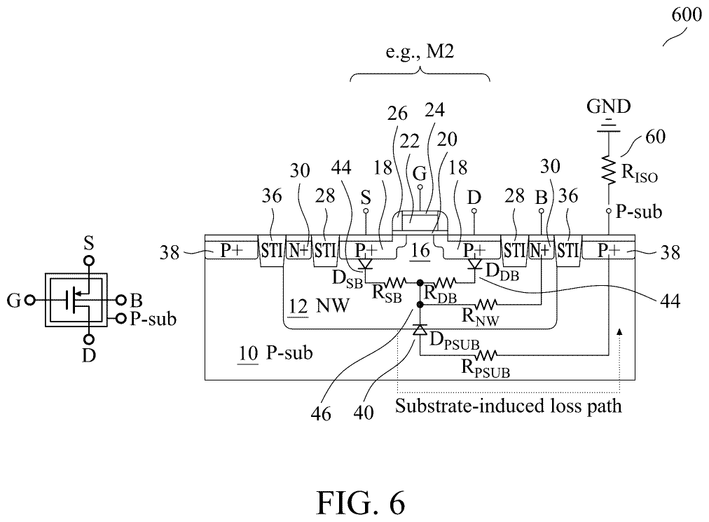

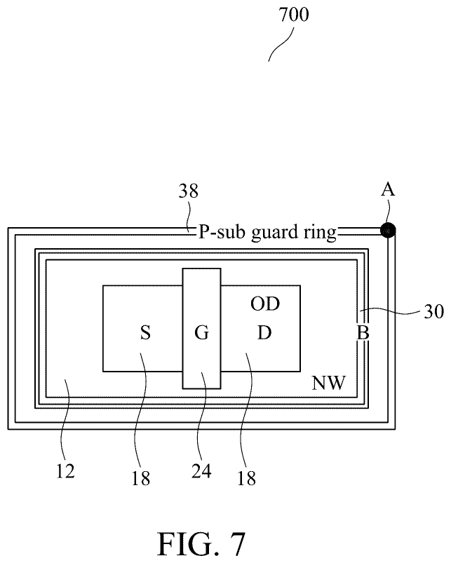

FIG. 6 is a cross-sectional view that illustrates an example transistor 600 (M₁ or M₂) of a cascode amplifier (e.g., 100A or 100B) in accordance with some embodiments. FIG. 7 is a plan view 700 that illustrates the example transistor 600 in FIG. 6 in accordance with some embodiments. In some embodiments, the transistor 600 in FIG. 6 can be implemented as a CG transistor M₂ of a cascode amplifier 100A in FIG. 1 or a cascode amplifier 100B in FIG. 2, in which the source of the CG transistor M₂ is not directly coupled to the supply voltage V_{DD}. In other embodiments, the transistor 600 in FIG. 6 can be implemented as a CS transistor M₁ of a cascode amplifier 100B in FIG. 2, in which the source of the CS transistor M₁ of the cascode amplifier 100B is not directly coupled to the supply voltage V_{DD} but rather coupled to the supply voltage V_{DD} through a source degeneration circuit 50. As shown in FIGS. 6 and 7, in order to perform high isolation while maintain ground potential for a semiconductor substate 10 of a transistor 600, the transistor 600 includes an insolation circuit 60 that couples the semiconductor substrate 10 of the transistor 600 to a ground voltage (GND) through a substrate contact 38. In some embodiments, the insolation circuit 60 has a resistor with a large resistance greater than about 1 k ohm, and effectively reduces substrate induced loss.

In some embodiments, the substrate contact 38 can be implemented as a substrate guard ring. A substrate guard ring is a structure used in semiconductor devices to prevent unwanted electrical noise or interference from affecting the performance of a circuit. The substrate guard ring can be a ring-shaped region, or other suitable-shaped region, that surrounds a particular area of an integrated circuit (IC) or a specific component within the IC. The substrate guard ring can be made of a conductive material, such as heavily doped silicon or metal (for example, copper, aluminum, or tungsten etc.). The substrate guard ring can help isolate sensitive parts of a circuit from electrical noise or interference that might be present in the substrate or nearby circuits. The substrate guard ring can also help provide a path to safely discharge any electrostatic buildup, protecting the sensitive components within the substrate guard ring from damage.

In some embodiments, as shown in FIGS. 6 and 7, the transistor 600 (e.g., CG transistor M₂ in the cascode amplifier 100A in FIG. 1) is formed over a semiconductor substrate 10 (e.g., p-substrate, or p-sub), which may be doped with a first conductive type material, e.g., a p-type material. As will be understood by one of ordinary skill in the art, semiconductor substrate 10 can be formed from a variety of materials including, but not limited to, bulk silicon, silicon-phosphorus (“SiP”), silicon-germanium (“SiGe”), silicon-carbide (“SiC”), germanium (“Ge”), silicon-on-insulator silicon (“SOI-Si”), silicon-on-insulator germanium (“SOI-Ge”), or combinations thereof.

In some embodiments, as shown in FIGS. 6 and 7, a well region or well 12 of a second conductive material, e.g., a n-type material is formed in substrate 10. In some embodiments, the well 12 (e.g., n-well) is formed by doping the semiconductor substrate 10 with a suitable n-type material, such as arsenic, phosphorus, antimony, or other Group V element, as will be understood by one of ordinary skill in the art.

In some embodiments, as shown in FIGS. 6 and 7, the source contact and the drain contact of the transistor 600 are formed by P+ regions 18 vertically adjacent to the upper surface of the well region 12, in the P+ regions 18 are doped with a suitable p-type dopant to a higher concentration than a concentration of n-type dopant in the well region 12 of n-type. The gate G of the transistor 600 is formed over a channel 16 that is disposed in the n-well region 12 and between P+ regions 18 by depositing a gate oxide 20 over the channel 16, forming a gate dielectric 22 over the gate oxide 20, and forming a gate electrode 24 over gate dielectric 22. Sidewalls 26 may be disposed on the sides of gate dielectric 22 and gate electrode 24.

In some embodiments, as shown in FIG. 6, shallow trench isolations (STIs) regions 28 are disposed laterally adjacent to P+ regions 18 in the upper surface of n-well 12. A STI region 28 laterally separates a P+ region 18 from a N+ region 30. STI regions 36 are formed in an upper surface of the substrate 10. An STI region 36 separates a N+ region 30 from an adjacent P+ region 38. P+ regions 38 are laterally disposed apart from STI regions 36 in the upper surface of substrate 10. In some embodiments, a P+ region 18 serves as a source contact of the transistor 600, another P+ region 18 serves as a drain contact of the transistor 600, and a N+ region 30 serves as a bulk contact of the transistor 600.

In some embodiments, a p-substrate 10 and a n-well 12 respectively have respective resistances R_{PSUB} and R_{NW}. A diode 40 is operatively formed at the interface of substrate 10 and n-well 12. A pair of diodes 44 (D_{SB} and D_{DB}) are operatively formed at the interfaces of n-well 12 and P+ regions 18, respectively. The cathodes of the pair of diodes 44 are coupled to the cathode of diode 40 respectively through a resistance R_{SB} and a resistance R_{DB} at a node 46, and the node 46 is coupled to a N+ region 30 through the n-well resistor R_{NW}. In some embodiments, the anode of diode 40 is coupled to a P+ region 38 through a substrate resistance R_{PSUB}. The P+ region 38 may form a substrate guard ring, and may serve as a substrate contact. In some embodiments, the P+ region 38 is coupled to the ground voltage (GND) through an isolation circuit 60. In order to perform high isolation between the substrate 10 and the ground voltage (GND), the isolation circuit 60 is formed to have a large resistance R_{ISO} to couple the p-doped substrate contact 38 (P+ region 38) to the ground voltage (GND). In some embodiments, the resistance of the isolation circuit 60 is greater than about 10 k ohm. In other embodiments, the resistance of the isolation circuit 60 is greater than about 20 k ohm. As such, the isolation circuit 60 of the transistor 600 with such a large resistance can minimize the substrate or well region induced loss, thereby effectively improving the gain of the cascode amplifier that utilizes such a transistor 600 as at least one stage.

In some embodiments, the transistor 600 having the substrate 10 coupled to the ground voltage thought the isolation circuit 60 as shown in FIG. 6 can be implemented in a CG transistor M₂ of a PMOS cascode amplifier 100A or 100B as shown in FIGS. 1 and 2, to reduce or prevent a substrate induced or a well region induced loss via the junction diode 40 D_{PSUB}, since the source of the transistor 600 is not directly connected to a supply voltage V_{DD}. In other embodiments, the transistor 600 having its substrate 10 coupled to the ground voltage thought the isolation circuit 60 as shown in FIG. 6 can be implemented as a CS transistor M₁ of a PMOS cascode amplifier 100B as shown in FIG. 2, in condition that the source contact and the bulk contact of the CS transistor M₁ are indirectly coupled to the supply voltage V_{DD} through a source degeneration circuit 50, to reduce or prevent a substrate induced or a well region induced loss via the junction diode 40 D_{PSUB}.

As shown in FIGS. 1, 2, 6 and 7, in some embodiments, a semiconductor device 600 includes a substrate 10 having a first conductive type (e.g., a p-doped substrate); a well region 12 formed within the substrate 10 and having a second conductive type (e.g., a n-well) opposite to the first conductive type; a first transistor (e.g., M₂) formed based on the well region 12. In some embodiments, the first transistor (e.g., M₂) includes a gate contact 24, a drain contact 18 with the first conductive type, a source contact 18 with the first conductive type, and a bulk contact 30 with the second conductive type. The source contact 18 and the bulk contact 30 of the first transistor 600 are electrically connected to each other. In case that neither the source contact 18 nor the bulk contact 30 of the first transistor 600 is directly connected to a supply voltage (V_{DD} in FIG. 1), a semiconductor device 600 includes an isolation circuit 60 that is formed over the substrate 10 and is coupled between a substrate contact A of the substrate guard ring 38 of the substrate 10 and a ground voltage (GND). In some embodiments, the isolation circuit 60 includes a resistor having a resistance greater than about 10 k ohm. In some embodiments, the substrate guard ring 38 has the first conductive type. In some embodiments, the first conductive type is p-type, and in other embodiments, the first conductive type is n-type.

In some embodiments, as shown in FIG. 6, a junction diode 40 is operatively formed between the well region 12 and the substrate 10. Due to the isolation circuit 60 coupled between the substrate 10 and the ground voltage (GND), the junction diode 40 is configured to block charges from the well region 12 toward the substrate 10. In some embodiments, the first transistor 600 is configured to function as a CG transistor M₂ of a cascode amplifier, where the source of the first transistor 600 is not directly connected to the supply voltage (V_{DD}). In other embodiments, the first transistor 600 is configured to function as a CS transistor M₁ of a cascode amplifier, in case that the source of the first transistor 600 is indirectly connected to the supply voltage (V_{DD}) through a source degeneration circuit 50 as shown in FIG. 2. In some embodiments, the source degeneration device 50 includes at least one of a second resistor 50A in FIG. 3, a quarter-wave transmission line 50B in FIG. 4, or an LC tank circuit 50C in FIG. 5.

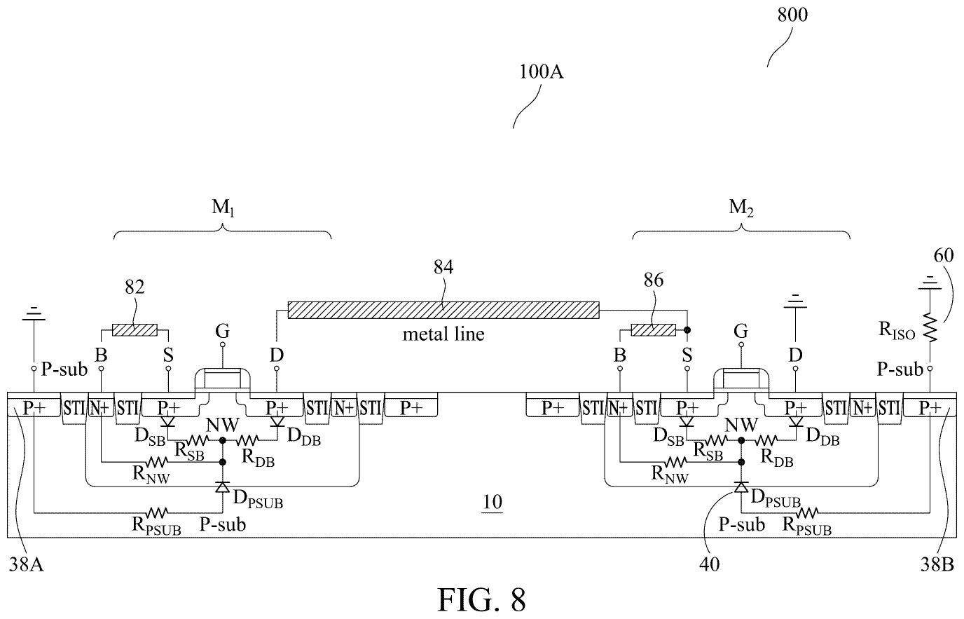

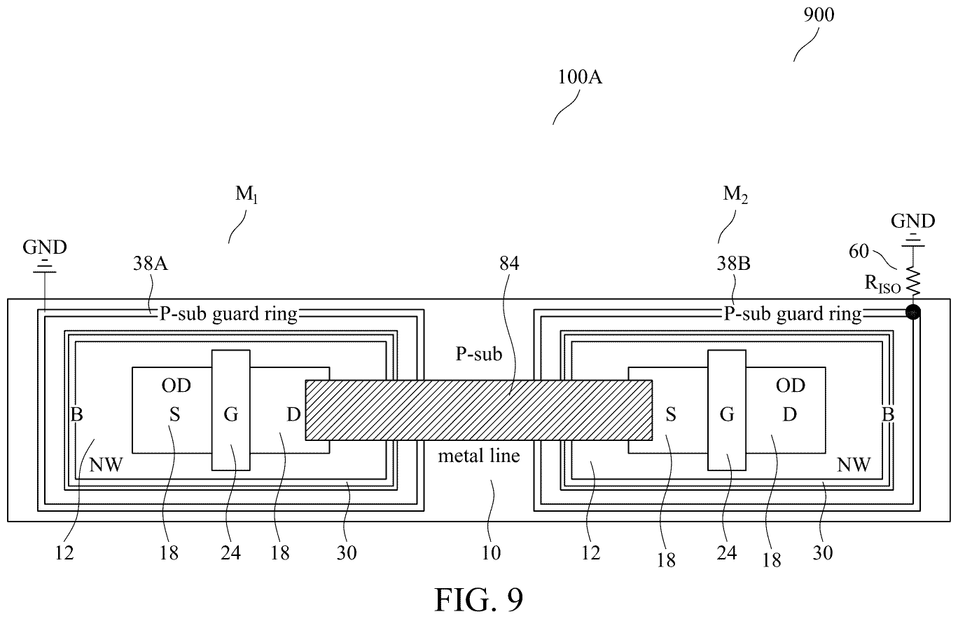

FIG. 8 is a cross-sectional view 800 that illustrates two transistors M₁ and M₂ of a cascode amplifier 100A in FIG. 1 in accordance with some embodiments. FIG. 9 is a plan view 900 that illustrates two transistors M₁ and M₂ of the cascode amplifier 100A (FIG. 1), in accordance with some embodiments. As shown, the two transistors M₁ and M₂ are formed in the first area and the second area of a substrate, respectively. The structures of two transistors M₁ and M₂ of the cascode amplifier 100A have been described with respect to FIG. 6. Referring to FIGS. 1, 6, 8 and 9, the CG transistor M₂ includes the isolation circuit 60 having a sufficiently large resistance coupled between the substrate contact A of the substrate guard ring 38B and the ground voltage (GND), as shown in FIG. 7, to reduce or prevent a substrate induced or a well region induced loss via the junction diode 40 D_{PSUB}.

As shown in FIGS. 1, 8 and 9, a cascode amplifier 100A includes a CS transistor M₁ coupled to a CG transistor M₂. In some embodiments, the cascode amplifier 100A is formed over a substrate 10. Each of the circuit elements of the cascode amplifier 100A may be implemented using p-type metal-oxide-semiconductor (PMOS) technology, n-type metal-oxide-semiconductor (NMOS) technology, or complementary metal oxide semiconductor (“CMOS”) technology. In some embodiments, the CS transistor M₁ has its source coupled to its bulk through a metal line 82, its drain coupled a source of the CG transistor M₂, and its gate coupled to input node 108 to receive to an input signal (such as an oscillating input signal) RF_{IN} in FIG. 1. In some embodiments, the gate of CS transistor M₁ is also coupled to a bias voltage source having a voltage V_{G1} via a resistor R_{G1} in FIG. 1. In some embodiments, node 110 also serves as an output node of the cascode amplifier 100A from which an output signal RF_{OUT} is output as shown in FIG. 1. In some embodiments, as shown in FIGS. 1, 8 and 9, a substrate guard ring 38A of CS transistor M₁ at a place A is coupled to the ground voltage (GND).

In some embodiments, as shown in FIGS. 1, 8 and 9, the CG transistor M₂ has its source coupled the drain of CS transistor M₁ through metal line 84, its bulk coupled to its source through metal line 86, its drain directly coupled the GND voltage, and its gate coupled to another bias voltage source having a voltage V_{G2} via another resistor R_{G2}. In some embodiments, a substrate guard ring 38B of CG transistor M₂ is coupled to the ground voltage (GND) through an isolation circuit 60. In some embodiments, the isolation circuit 60 is formed over the substrate 10 and coupled between the substrate 10 and a ground voltage (GND) through the substrate guard ring 38B as a substrate contact adjacent to CG transistor M₂.

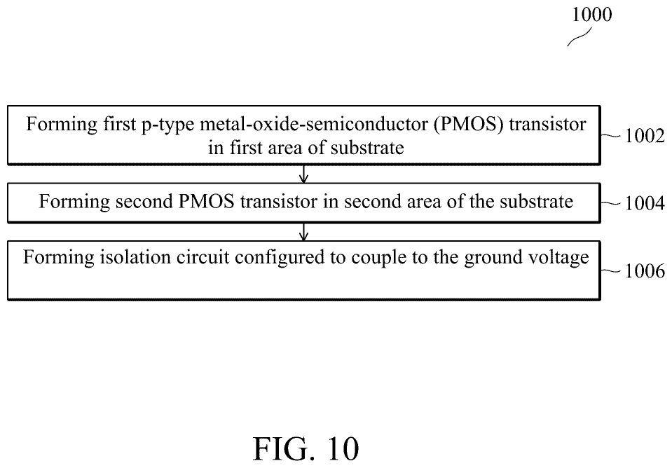

FIG. 10 is flow diagram that illustrates an example method 1000 of forming a cascode amplifier (e.g., 100A as shown in FIGS. 1, 8 and 9) in accordance with some embodiments. It is understood that additional operations can be provided before, during, and after processes discussed in FIG. 10, and some of the operations described below can be replaced or eliminated, for additional embodiments of the method. The order of the operations/processes may be interchangeable and at least some of the operations or processes may be performed in a different sequence. In some embodiments, at least two or more operations or processes are performed overlapping in time, or almost simultaneously.

In some embodiments, the operations of the method 1000 can be utilized to form a cascode amplifier 100A including a first p-type metal-oxide-semiconductor (PMOS) transistor M₁ formed over a first area of a substrate 10 and operatively configured as a common-source (CS) stage, and a second PMOS transistor M₂ formed over a second area of the substrate 10 and operatively configured as a common-gate (CG) stage, and an isolation circuit 60 that couples a substrate contact 38B of the substrate 10 adjacent to the second PMOS transistor M₂ to the ground voltage (GND), as shown in FIGS. 1, 8, and 9.

As shown in FIGS. 1, 8, 9 and 10, in some embodiments, operation 1002 includes forming, over a first area of the substrate 10, a first p-type metal-oxide-semiconductor (PMOS) transistor M₁ that is operatively configured as a first stage of the cascode amplifier 100A. In some embodiments, the first stage of the cascode amplifier 100A is a CS transistor M₁. In some embodiments, the semiconductor substrate 10 can be formed from a variety of materials including, but not limited to, bulk silicon, silicon-phosphorus (“SiP”), silicon-germanium (“SiGe”), silicon-carbide (“SiC”), germanium (“Ge”), silicon-on-insulator silicon (“SOI-Si”), silicon-on-insulator germanium (“SOI-Ge”), or combinations thereof.

In some embodiments, as shown in FIGS. 1, 6, 8, 9 and 10, the operation 1002 of forming the first PMOS transistor M₁ is performed in a Front End Of Line (FEOL), and includes: for example, forming a first gate contact or electrode 24 configured to receive an input signal; forming a first drain contact 18; forming a first source contact 18 configured to be coupled to a supply voltage V_{DD}; and forming a first bulk contact 30 configured to be coupled to the first source contact 18. Various methods of photolithography, etching, and deposition can be used to form these elements of the first PMOS transistor M₁.

Next, as shown in FIGS. 1, 8, 9 and 10, in some embodiments, operation 1004 includes forming, over a second area of the substrate 10, a second PMOS transistor M₂ that is configured as a second stage of the cascode amplifier 100A. In some embodiments, the second stage of the cascode amplifier 100A is a CG transistor M₂. Operation 1004 can be performed previously than, subsequently than, or concurrently with operation 1002.

In some embodiments, as shown in FIGS. 1, 6, 8, 9 and 10, the operation 1004 of forming the second PMOS transistor M₂ is performed in the FEOL, and includes: for example, forming a second gate contact 24; forming a second drain contact 18 coupled to a ground voltage; forming a second source contact 18 configured to be coupled to the first drain contact 18 of the first PMOS transistor M₁; and forming a second bulk contact 30 configured to be coupled to the second source contact 18. Various methods of photolithography, etching, and deposition can be used to form these elements of the second PMOS transistor M₂.

Next, as shown in FIGS. 1, 8, 9 and 10, in some embodiments, operation 1006 includes forming an isolation circuit 60 in a corresponding one of the plurality of metallization layers (not shown) in a Back End Of Line (BEOL). In some embodiments, the isolation circuit 60 is configured to electrically couple the substrate 10 to the ground voltage (GND) through a substrate contact or substrate guard ring 38B that is adjacent to the second PMOS transistor M₂. In some embodiments, the isolation circuit 60 includes a resistor having a large resistance greater than about 10 k ohm, and in other embodiments, the large resistance is greater than about 20 k ohm.

In some embodiments, referring to e.g., FIGS. 1 and 8, in the BEOL, a source of CS transistor M₁ is coupled to a bulk of CS transistor M₁ through a metal line 82, a drain of CS transistor M₁ is coupled a source of CG transistor M₂ through a metal line 84, and a gate of CS transistor M₁ is coupled to an input node 108 to receive to an input signal (such as an oscillating input signal) RF_{IN}. In some embodiments, the gate of CS transistor M₁ is also coupled to a bias voltage source having a voltage V_{G1} via a resistor Roi as shown in FIG. 1. In some embodiments, node 110 also serves as an output node of the cascode amplifier 100A from which an output signal RF_{OUT} is output as shown in FIG. 1. In some embodiments, as shown in FIGS. 1, 8 and 9, a substrate contact or guard ring 38A of CS transistor M₁ is directly coupled to the ground voltage (GND) in case that the source of CS transistor M₁ is directly coupled to a supply voltage (V_{DD}).

In some embodiments, referring to e.g., FIGS. 1 and 8, in the BEOL, a source of CG transistor M₂ is coupled the drain of CS transistor M₁ through metal line 84, the bulk of CG transistor M₂ is coupled to the source of CG transistor M₂ through metal line 86, the drain of CG transistor M₂ is directly coupled the GND voltage, and the gate of CG transistor M₂ is coupled to another bias voltage source having a voltage V_{G2} via another resistor R_{G2}. In some embodiments, a substrate guard ring 38B of CG transistor M₂ is coupled to the ground voltage (GND) through an isolation circuit 60. In some embodiments, in the BEOL, the isolation circuit 60 with a large resistance (e.g., greater than 1 k ohm) is formed over the substrate 10 and coupled between the substrate 10 and a ground voltage (GND) through the substrate guard ring 38B as a substrate contact adjacent to CG transistor M₂.

In other embodiments, as shown in FIG. 2, in case that a source degeneration circuit 50 is formed in one (e.g., M3) of the metallization layers (e.g., M0, M1, M2, M3, M4, M5 . . . not shown) and configured to electrically couple the first source contact of CS transistor M₁ to the supply voltage (V_{DD}), another isolation circuit 60′ can be formed in one of the metallization layers and configured to electrically couple the substrate 10 to the ground voltage (GND). As such, by utilizing an isolation circuit 60 or an isolation circuit 60′ in the ways as aforementioned, the substrate-induced loss can be effectively reduced or even prevented, thereby advantageously enhancing gain performance of an amplifier, such as a low noise amplifier (LNA) or a power amplifier (PA).

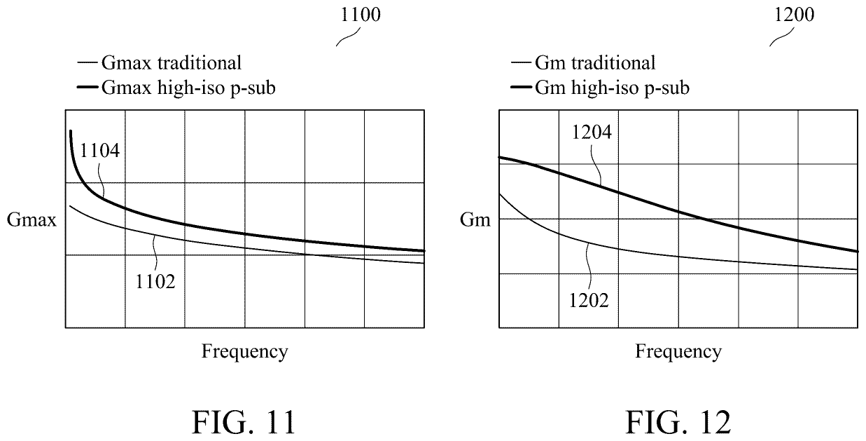

FIG. 11 is a maximum available gain (Gₘₐₓ) versus frequency graph comparing the Gₘₐₓ of a traditional LNA that does not include a high isolation circuit that electrically couples a substrate thereof to the ground (trace 1102) to the Gₘₐₓ of an LNA that does include a high isolation circuit that electrically couples the substrate thereof to the ground (trace 1104) in accordance with the present disclosure. As shown in FIG. 11, trace 1104 achieved by an LNA in accordance with the present disclosure is better than trace 1102 achieved by a traditional LNA.

FIG. 12 is a maximum available transconductance (Gₘ) versus frequency graph comparing the Gₘ of a traditional LNA that does not include a high isolation circuit that electrically couples a substrate thereof to the ground (trace 1202) to the Gₘ of an LNA that does include a high isolation circuit that electrically couples the substrate thereof to the ground (trace 1204) in accordance with the present disclosure. As shown in FIG. 12, trace 1204 achieved by an LNA in accordance with the present disclosure is better than trace 1202 achieved by a traditional LNA.

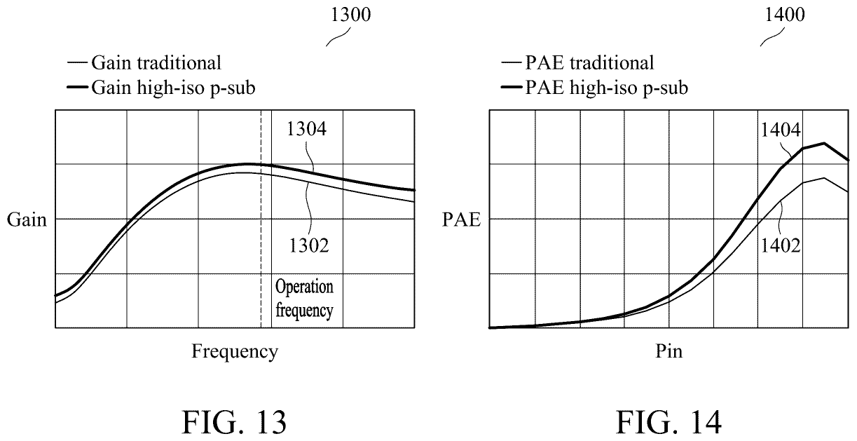

FIG. 13 is a gain versus frequency graph comparing the gain of a traditional LNA that does not include a high isolation circuit that electrically couples a substrate thereof to the ground (trace 1302) to the gain of an LNA that does include a high isolation circuit that electrically couples the substrate thereof to the ground (trace 1304) in accordance with the present disclosure. As shown in FIG. 13, trace 1304 achieved by an LNA in accordance with the present disclosure is better than trace 1302 achieved by a traditional LNA.

FIG. 14 is a power-added-efficiency (PAE) vs input power (Pin) graph comparing the PAE of a traditional LNA that does not include a high isolation circuit that electrically couples a substrate thereof to the ground (trace 1402) to the PAE of an LNA that does include a high isolation circuit that electrically couples the substrate thereof to the ground (trace 1404) in accordance with the present disclosure. As shown in FIG. 14, trace 1404 achieved by an LNA in accordance with the present disclosure is better than trace 1402 achieved by a traditional LNA.

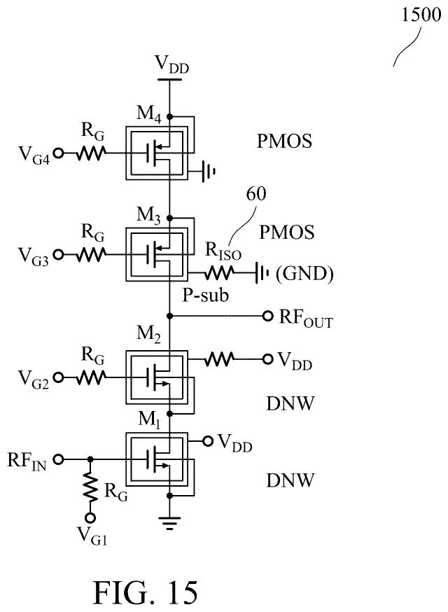

FIG. 15 is a schematic view 1500 that illustrates an embodiment of a Complementary Metal-Oxide-Semiconductor (CMOS) cascode amplifier 1500 in which PMOS and NMOS substrates are used in accordance with some embodiments. As shown in FIG. 15, the CMOS cascode amplifier 1500 includes a first transistor M₁ and a second transistor M₂ that are implemented with a floating deep n-well (“DNW”), and also includes a third transistor M₃ and a fourth transistor M₄ that are implemented with a PMOS substrate. As shown in FIG. 15, for example, the PMOS transistor M₃, functioning as a CG transistor and not directly coupled to a supply voltage (V_{DD}), includes an isolation circuit 60 that couples a P-doped substrate (P-sub) to the ground voltage (GND). In some embodiments, the isolation circuit 60 has a large resistance greater than 1 k ohm. In some embodiments, the CMOS cascode amplifier 1500 can be applied as a telescopic cascode amplifier.

In one aspect of the present disclosure, a semiconductor device is disclosed. The semiconductor device includes a substrate having a first conductive type; a well region formed within the substrate and having a second conductive type opposite to the first conductive type; a first transistor formed based on the well region, wherein the first transistor includes a gate contact, a drain contact with the first conductive type, a source contact with the first conductive type, and a bulk contact with the second conductive type; and an isolation circuit formed over the substrate and coupled between the substrate and a ground voltage through a substrate contact.

In another aspect of the present disclosure, a circuit is disclosed. The circuit includes: a first p-type metal-oxide-semiconductor (PMOS) transistor formed over a substrate, and including a first gate contact configured to receive an input signal, a first drain contact, a first source contact coupled to a supply voltage, and a first bulk contact coupled to the first source contact; a second PMOS transistor formed over the substrate, and including a second gate contact, a second drain contact coupled to a ground voltage, a second source contact coupled to the first drain contact of the first PMOS transistor, and a second bulk contact connected to the second source contact; and an isolation circuit configured to couple a first contact of the substrate adjacent to the second PMOS transistor to the ground voltage. The first PMOS transistor and the second PMOS transistor operatively serves as a common-source stage and a common-gate stage of a cascode amplifier, respectively.

In yet another aspect of the present disclosure, a method for forming a cascode amplifier is disclosed. The method includes forming, over a substrate, a first p-type metal-oxide-semiconductor (PMOS) transistor operatively configured as a first stage of the cascode amplifier; forming, over the substrate, a second PMOS transistor operatively configured as a second stage of the cascode amplifier; and forming a plurality of metallization layers over the first PMOS transistor and the second PMOS transistor. Forming the first PMOS transistor includes forming a first gate contact configured to receive an input signal; forming a first drain contact; forming a first source contact configured to be coupled to a supply voltage; and forming a first bulk contact configured to be coupled to the first source contact. Forming the second PMOS transistor includes forming a second gate contact; forming a second drain contact coupled to a ground voltage; forming a second source contact configured to be coupled to the first drain contact of the first PMOS transistor; and forming a second bulk contact configured to be coupled to the second source contact. Forming the plurality of metallization layers includes forming an isolation circuit in a corresponding one of the plurality of metallization layers. The isolation circuit is configured to electrically couple the substrate to the ground voltage.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a first conductive type;
a well region formed within the substrate and having a second conductive type opposite to the first conductive type;
a first transistor formed based on the well region, wherein the first transistor includes a gate contact, a drain contact with the first conductive type, a source contact with the first conductive type, and a bulk contact with the second conductive type; and
an isolation circuit formed over the substrate and coupled between the substrate and a ground voltage through a substrate contact.

2. The semiconductor device of claim 1, wherein the isolation circuit comprises a first resistor having a resistance greater than about 10 k ohm.

3. The semiconductor device of claim 1, further comprising:
a junction diode operatively formed between the well region and the substrate;
wherein, with the isolation circuit coupled between the substrate and the ground voltage, the junction diode is configured to block charges from the well region toward the substrate.

4. The semiconductor device of claim 1, wherein the substrate contact has the first conductive type.

5. The semiconductor device of claim 1, wherein the source contact and the bulk contact are electrically connected to each other, and neither the source contact nor the bulk contact is directly connected to a supply voltage.

6. The semiconductor device of claim 1, wherein the first transistor is configured to function as a common-gate (CG) stage of a cascode amplifier, and wherein the cascode amplifier includes a second transistor configured to function as a common-source (CS) stage.

7. The semiconductor device of claim 6, wherein the second transistor includes a gate contact configured to receive an oscillating input signal.

8. The semiconductor device of claim 6, wherein the second transistor includes a source contact and a bulk contact commonly coupled to a supply voltage via a source degeneration circuit.

9. The semiconductor device of claim 8, wherein the source degeneration device includes at least one of a second resistor, an LC tank, or a quarter-wave transmission line.

10. The semiconductor device of claim 8, wherein the source contact and the bulk contact of the second transistor are directly connected to the supply voltage.

11. The semiconductor device of claim 1, wherein the drain contact of the first transistor is coupled to the ground voltage, and the gate contact of the first transistor is coupled to a bias voltage.

12. A circuit, comprising:
a first p-type metal-oxide-semiconductor (PMOS) transistor formed over a substrate, and including a first gate contact configured to receive an input signal, a first drain contact, a first source contact coupled to a supply voltage, and a first bulk contact coupled to the first source contact;
a second PMOS transistor formed over the substrate, and including a second gate contact, a second drain contact coupled to a ground voltage, a second source contact coupled to the first drain contact of the first PMOS transistor, and a second bulk contact connected to the second source contact; and
an isolation circuit configured to couple a first contact of the substrate adjacent to the second PMOS transistor to the ground voltage;
wherein the first PMOS transistor and the second PMOS transistor operatively serves as a common-source stage and a common-gate stage of a cascode amplifier, respectively.

13. The amplifier of claim 12, wherein the first source contact is coupled to the supply voltage via a source degeneration circuit, and wherein a second contact of the substrate adjacent to the first PMOS transistor is connected to the ground voltage through another isolation circuit.

14. The amplifier of claim 13, wherein the source degeneration circuit includes at least one of a resistor, an LC tank, or a quarter-wave transmission line.

15. The amplifier of claim 12, wherein the first PMOS transistor is formed within a first n-well region formed within the substrate that is p-doped.

16. The amplifier of claim 12, wherein the second PMOS transistor is formed within a second n-well region formed within the substrate that is p-doped.

17. A method for forming a cascode amplifier, comprising:
forming, over a substrate, a first p-type metal-oxide-semiconductor (PMOS) transistor operatively configured as a first stage of the cascode amplifier, wherein forming the first PMOS transistor comprises:
forming a first gate contact configured to receive an input signal;
forming a first drain contact;
forming a first source contact configured to be coupled to a supply voltage; and
forming a first bulk contact configured to be coupled to the first source contact;
forming, over the substrate, a second PMOS transistor operatively configured as a second stage of the cascode amplifier, wherein forming the second PMOS transistor comprises:
forming a second gate contact;
forming a second drain contact coupled to a ground voltage;
forming a second source contact configured to be coupled to the first drain contact of the first PMOS transistor; and
forming a second bulk contact configured to be coupled to the second source contact; and
forming a plurality of metallization layers over the first PMOS transistor and the second PMOS transistor, wherein forming the plurality of metallization layers comprises:
forming an isolation circuit in a corresponding one of the plurality of metallization layers, wherein the isolation circuit is configured to electrically couple the substrate to the ground voltage.

18. The method of claim 17, wherein the isolation circuit comprises a resistor having a resistance greater than about 10 k ohm.

19. The method of claim 17, wherein forming the plurality of metallization layers further comprises:
forming a source degeneration circuit in a corresponding one of the metallization layers, wherein the source degeneration circuit is configured to electrically couple the first source contact to the supply voltage; and
forming another isolation circuit in a corresponding one of the metallization layers, wherein the another isolation circuit is configured to electrically couple the substrate to the ground voltage.

20. The method of claim 19, wherein the another isolation circuit comprises another resistor having a resistance greater than about 10 k ohm.
